(19) United States
(12) Patent Application Publication
(10) Pub. No.: US 2009/0272642 A1
(43) Pub. Date: Nov. 5, 2009

(54) METHOD AND ARRANGEMENT FOR PRODUCING CONTACTS ON PHOTOVOLTAIC ELEMENTS WITHOUT CARRIER SUBSTRATE

(75) Inventors: Ekkehart Reinhold, Langebrueck (DE); Steffen Mosshammer, Rabenau (DE); Martin Dimer, Dresden (DE); Roland Koenig, Markersdorf (DE); Joerg Faber, Mueglitztal OT Muehlbach (DE); Hans-Christian Hecht, Weinboehla (DE)

Correspondence Address: HESLIN ROTHENBERG FARLEY & MESITI PC, 5 COLUMBIA CIRCLE, ALBANY, NY, 12203, US

(73) Assignee: VON ARDENNE ANLAGENTECHNIK GMBH, Dresden (DE)

(21) Appl. No.: 12/248,927

(22) Filed: Oct. 10, 2008

(30) Foreign Application Priority Data
Apr. 30, 2008 (DE) 10 2008 021 765.4

(51) Int. Cl. C23C 14/35

(52) U.S. Cl. 204/192.17; 204/298.02

(57) ABSTRACT

Please amend the Abstract of the Disclosure to read as follows. In accordance with 37 CFR §1.72, the abstract is submitted herewith on a separate sheet of paper, following page 9 of this amendment.

### SUMMARY

A method and an arrangement for fabricating contacts on carrier substrate-free photovoltaic elements is intended for fabricating contacts on photovoltaic elements. The contact layer is formed in its entirely in a vacuum process.

A method for fabricating contacts on carrier substrate-free photovoltaic elements is described below. In this case the photovoltaic elements are designed with a photoactive front side and a rear side, with which contact is to be made, and the rear side is provided with an electrically conducting contact layer, which forms the contacts.

Furthermore, an arrangement, which is intended for fabricating contacts on carrier substrate-free photovoltaic elements and which comprises at least one evacuatable vacuum coating chamber, is described.

There exist a number of methods for metallizing flat substrates, for example, wafers, which are intended, for example, for forming rear side contacts of a solar cell for current derivation and which are manufactured on the basis of crystalline silicon.

A first method for the contacting of solar cells works in such a way that a conductive paste is applied, for example, by screen printing. In a subsequent tempering process this paste is formed for electrical contact.

Owing to the limits of this method, other metallization methods were envisaged for new cell designs.

One possible method consists of producing the metallized layers by sputter deposition on thin metal layers (seed layer) and then reinforcing these layers in an additional process step. The reinforcement can be performed by dip soldering, electrodeposition or currentless chemical deposition. This method is complicated and cost intensive owing to the many process steps, as a result of which the productivity is limited by low rates while at the same time the heat inputs for the sputtering process are high.

Another drawback especially in the case of a metallization with pastes lies in the mechanical stresses induced by the varying coefficients of expansion of the materials that are being used. The increasing trends towards ever thinner wafers means that this drawback and consequently the rejection of the wafers will continue to intensify. In addition, parasitic interlayers may form that adversely affect the properties of the contact in terms of its electrical conductivity and service life.

Therefore, the object is to provide below a method, which is intended for fabricating contacts on photovoltaic elements and with which the drawbacks of the prior art methods are overcome.

Therefore, the method for fabricating contacts on carrier substrate-free photovoltaic elements comprising a photoactive front side and a rear side, with which contact is to be made, proposes that the contact layer be form ed in its entirety in a vacuum coating process.

According to the invention, the contact layer that is to be fabricated is not made by a plurality of different successive techniques, but rather made in its entirety in a vacuum coating process.

One embodiment of the method provides that the contact layer be fabricated by means of a thermally driven vacuum high rate coating process in a through-feed procedure in a system throughflow without vacuum interruption.

One special embodiment provides that the vacuum high rate coating technique is a high power electron beam evaporation technique.

An additional embodiment provides that the through-feed procedure is a dynamic procedure, in which the vacuum high rate coating technique is a continuously operating process, in which the photovoltaic elements are moved through a coating zone at a speed greater than zero.

The contacts are fabricated, for example, in such a manner that the substrates (solar cells), with which contact is to be made, are guided through an inline coating system, which operates continuously in accordance with the through-feed method. To this end, the substrates are placed advantageously on a carrier in such a way that the surface, which is to be coated, remains free. The carriers, which are populated in this way, are fed at least through the coating zone of the inline coating system at a rate greater than zero, so that in the process sections, in which vacuum conditions prevail, the contacts are fabricated by means of a thermally driven vacuum high rate coating technique. In this case the vacuum high rate coating technique is, for example, a high power electron beam evaporation technique.

The described method is a vacuum high rate coating process, which works continuously, that is, the vapor generation is not interrupted.

The method of thermal vapor deposition in a vacuum makes it possible to achieve an improvement in making contact with the surface as compared to the metallization variant with the application of a paste, because the parasitic interlayers, like oxides or water, are suppressed.

One design variant of the invention provides that the contact layer is deposited at a constant layer thickness growth until the desired thickness is reached.

An additional design variant of the invention provides that the contact layer composed of successive constant individual sections is deposited.

According to the invention, the contact layer, which is form ed in a vacuum coating process, is formed in such a manner that its layer thickness growth increases steadily until the contact layer reaches a specified desired thickness. Thus, a multilayer system is produced by successive coating steps.

In this case the contact layer can also be made of a plurality of superposed individual sections. In this case the layer thickness growth inside the individual sections that are to be formed increases steadily at least during the formation of the respective individual section.

Another embodiment provides that a dynamic coating rate greater than 0.5 μm*m/min is set.

An additional embodiment provides that a temperature for the photovoltaic elements is chosen in such a way that it does not exceed 420° C. in situations, in which photovoltaic elements made of silicon are used.

When forming the contact layer, special attention must be paid to the heat input in order to avoid thermal damage to the cells. This feature is especially important for the thin wafers that are being increasingly used. Since in this case the final temperature is determined by the heat that is dissipated by thermal radiation (therefore, the thermal capacity of the wafer plays a subordinate role), it is necessary, according to the invention, to expand the coating process, which occurs at a correspondingly high dynamic coating rate, to include an adapted coating zone, where the maximum temperature, exhibited by the substrate as a result of the heat input of the coating process and the thermal radiation of the substrate (wafer), stays below a specified temperature limit. This feature is achieved by selecting an appropriately wide angular range of the vapor propagation in the transport direction of the substrate and/or by arranging a plurality of vapor sources in the transport direction of the substrate.

One embodiment of the invention provides that the contact layer is deposited as a multilayer system, which comprises at least two sub layers and which is produced in a vacuum by successive coating steps.

Another embodiment provides that the contact layer is designed as a gradient layer made of a variety of materials.

A special embodiment provides that the contact layer consisting of at least two interpenetrating particle flows per particle source is designed as a homogeneously mixed layer.

The contact layer may be fabricated in a number of different ways. One option is to design the contact layer as a multilayer system, which can be realized, for example, by a plurality of coating steps that are carried out in succession.

Another option for designing the contact layer is to design the contact layer as a gradient layer made of a variety of materials.

In addition, the contact layer can also be designed as a mixed layer.

To this end, the coating zone exhibits at least two particle sources, the particle flows of which interpenetrate and form the contact layer as a homogeneously mixed layer.

One embodiment provides that the contact layer is a solderable or bondable layer.

An additional embodiment provides that a solderable or bondable layer, which is deposited on the contact layer in vacuum sequence, is a sublayer of the multilayer system.

In order to provide in a subsequent step the contact layer of the photovoltaic element with, for example, wires for conducting current, it is necessary for the contact layer to be, at least indirectly, solderable or bondable. This feature can be achieved by designing the contact layer itself as a solderable or bondable layer or by depositing subsequently a solderable or bondable layer, for example, as a layer of a multilayer system, on the contact layer without vacuum interruption. Thus, it is possible to deposit, for example, a conducting layer made of aluminum, on which then a solderable layer made of copper is deposited.

Another embodiment provides that before or after the deposition of the contact layer, an additional layer is applied by magnetron sputtering.

An additional design provides that the additional layer is a layer system.

A special design provides that the additional layer is a gradient layer.

Another embodiment provides that the additional layer is produced by constant layer thickness growth.

According to the invention, an additional layer can be applied by magnetron sputtering. This additional layer can be arranged below the contact layer, thus, deposited prior to the fabrication of the contact layer, on the carrier-free substrate. In another variant the additional layer is deposited on the contact layer after the fabrication of the contact layer.

The additional layer may be designed as a layer system or as a gradient layer. In this case the additional layer is produced by a constant layer thickness growth.

One embodiment of the invention provides that between two successive process steps, which are locally separated from each other in a coating system and which exhibit varying process pressure, the pressure is uncoupled from each other selectively by means of apertures, flow resistors, actively pumped compartments or valves.

In this way the inventive vacuum coating process guarantees that the contact layer is fabricated in a system through-feed without vacuum interruption. At the same time the requirements of the various process conditions, for example, for the formation of a multilayer system, are satisfied.

One design provides that the contact layer contains by choice aluminum and/or copper.

Highly electrically conductive materials, like aluminum, silver or copper, are used advantageously to fabricate the contact layer.

Another design provides that a solderable layer or a bondable layer is deposited on the contact layer in vacuum sequence.

According to the method, following the fabrication of the contact layer without vacuum interruption, a solderable or bondable layer can be deposited on the contact layer. Thus, the photovoltaic element can be connected, for example, to wires for current derivation in the next step of the assembly process.

One embodiment provides that the solderable or bondable layer, which is deposited on the contact layer in vacuum sequence, is an additional layer.

The solderable or bondable layer can also be fabricated as an interlayer, which is applied by magnetron sputtering.

An additional embodiment provides that the photovoltaic elements are coated so as to be structured in that the photovoltaic elements are coated through a mobile or immobile mask.

Thus, it is guaranteed that not the entire rear side, with which contact is to be made, is provided with the contact layer, but rather only the subarea that is intended for this purpose. The structuring can be done with immobile masks, which are mounted stationarily in the process chamber and past which the substrates move. Another possibility consists of carrying along a mask at the speed of the substrate and in parallel to this substrate at least in the coating zone. However, a mask may also be placed with the substrate on the carrier.

A special design provides that an electron beam is directed to a crucible with the aid of an additional magnetic field in the evaporator chamber, while at the same time the predominant portion of the back-scattered electrons are kept away from the substrate by means of the deflecting field.

In order to prevent the back-scattered electrons from raising even higher the temperature of the substrate, the effect of an additional magnetic field in the evaporator chamber is used. Thus, between 70 to 99 percent of the back-scattered electrons can be kept away from the substrate.

Therefore, an arrangement, which is intended for fabricating contacts on carrier substrate-free photovoltaic elements and which comprises at least one evacuatable vacuum coating chamber, proposes that the vacuum coating chamber exhibits means for fabricating a contact layer.

One design provides that the means for fabricating a contact layer are first sources for the particle flow of the thermally driven vacuum high rate coating process. In this case the first sources are positioned in the vacuum coating chamber transversely to the transport direction of the substrate.

According to the invention, the vacuum coating chamber exhibits means, which are intended for fabricating a contact layer and which are, for example, first sources for the particle flow of the thermally driven vacuum high rate coating process. This source can consist of a single source or a group of sources in order to improve the homogeneity over the entire breadth of the coating.

These sources may be oriented transversely or longitudinally to the substrate transport direction.

The sources for the particle flow of the thermally driven vacuum high rate coating process are positioned transversely to the transport direction of the substrate in order to achieve a large area coating with a homogeneous layer thickness distribution.

The sources for the particle flow of the thermally driven vacuum high rate coating process are positioned longitudinally to the transport direction of the substrate in such a way that the arrangement of the sources, which are produced by the thermally driven vacuum high rate coating technique, for the particle flow longitudinally to the transport direction of the substrate is chosen in such a way that the heat input during the entire coating period is distributed in such a way that the momentary temperature of the substrate does not exceed the tolerable maximum temperature of the substrate.

Another design provides that additional apertures are arranged in the particle flow between the first source and the substrate.

The additional apertures in the particle flow make it possible to achieve a further improvement in the homogeneity of the transverse distribution of the layer thickness of the contact layer.

A special design provides that second sources are positioned as additional means for fabricating a contact layer for a second particle flow of the thermally driven vacuum high rate coating process in the substrate transport direction behind the first sources.

Another option for the distribution of sources consists of arranging a second source or group of sources in the substrate transport direction behind the first source or group of sources. With this arrangement it is possible to fabricate, for example, contact layers composed of superposed, constantly growing individual layers.

One embodiment provides that an absorbing radiation collector having a high thermal capacity or active cooling is mounted behind the photovoltaic elements, which are to be coated, in the vacuum coating chamber.

With this arrangement of the radiation collector an improvement in the thermal radiation balance of the substrates is achieved. The radiation collector may also be connected to a cooling cycle.

Another embodiment provides that radiation shields are mounted in the vacuum coating chamber in the area of the evaporator environment that does not output steam.

The thermal radiation input into the substrate is reduced by means of this radiation shield.

A special design provides that a sputter source is mounted in the substrate transport direction so as to be inserted as a subsequent addition in another vacuum coating chamber.

A sputter source is mounted in the substrate transport direction so as to be inserted as a subsequent addition in another vacuum coating chamber, in order to deposit, for example, an additional layer. This separation by means of an additional chamber, which is separated from the upstream vacuum coating chamber, guarantees the process conditions that are necessary for the electron beam evaporation process.

Another design provides that an electron beam evaporation results from a water-cooled copper crucible.

According to the invention, a water-cooled copper crucible is used for the electron beam evaporation.

Furthermore, it is provided that the electron beam evaporation results from a ceramic crucible or from a water-cooled copper crucible that is lined with ceramic.

In an additional embodiment a ceramic crucible or a ceramic-lined crucible, which may also be operated with a water cooling, is used for the electron beam evaporation.

Another design provides that the ceramic of the ceramic crucible is manufactured on the basis of aluminum oxide or boron nitride.

Aluminum oxide or boron oxide may be used advantageously as the materials for manufacturing such a ceramic crucible.

The solution shall be explained in detail below with the aid of one embodiment.

The wafer, on which the contacts are supposed to be fabricated, are placed in carriers having a surface-optimized wafer support. Thus, a large area of the wafers remains free for the process steps for fabricating the contact layer. The carriers are moved continuously and, working on the basis of the inline principle, through the coating system and coated, for example, from below.

The contacts are made, for example, as multilayer systems by means of a plurality of evaporation systems in one process section or a variety of process sections of the coating system.

A first layer, made of aluminum, can be fabricated in such a way that in a next step a second solderable layer, for example, made of silver, is applied on said first layer. This formation of the layers takes place within a system feed-through and, thus, without vacuum interruption. Therefore, parasitic interlayers are suppressed, and the service life, the adhesion and the electric conductivity of the fabricated contacts are improved. The temperature of the evaporation material, located under the wafers, is raised by means of an electron beam. This electron beam, which is generated obliquely from the bottom and deflected by means of a magnetic field, impinges on the evaporation material. Another variant consists of generating the electron beam in such a manner that it impinges laterally obliquely from the top on the evaporation material and raises the temperature of said material.

The second layer is applied, for example, by means of magnetron sputtering (under the condition that this second layer is significantly thinner than the Al layer) or also by a thermal evaporation technique.

In the described method the complete rear side contact is fabricated on the basis of physical deposition techniques in a vacuum.

The method is distinguished by a long term stable process having high transverse homogeneity of the vapor density distribution.

It could be demonstrated that owing to the deflecting field almost all of the scattered electrons could be kept away from the substrate and that the very small remaining portion of particles, loaded on the substrate, does not induce any negative effects.

The method is suitable for coating flat substrates having a thickness that may be below the current standard substrate thickness for wafers. Therefore, the method is also suitable, for example, for a wafer thickness below 150 μm.

With suitable parameterization of the process data, like the coating rate and/or the process pressure, it is possible to set by choice the structure and growth properties of the metallized layer. As a result, the electrical and mechanical properties of the deposited metallized layers, thus the contacts, can be influenced.

In situations, where the dynamic coating rate is predetemined, the length of the coating zone is adapted in such a manner that the resulting thermal radiation power at a tolerable maximum temperature of the substrate is necessary in order to emit again through thermal radiation that portion of the inputted process heat of the coating process that would lead to an overshooting of an allowable maximum temperature in the energy balance of the substrate.

The vacuum high rate coating technique is a thermal evaporation process, which functions, for example, at a dynamic coating rate >0.5 μm*m/min.

The electron beam high rate coating technique functions in such a manner that as the substrates flow through the system, the substrates are coated from the bottom. To this end, the substrates are moved past the evaporation material in the process section in the inline coating system. A special embodiment of the method consists of shooting in the electron beam not obliquely from the top, but rather obliquely from the bottom and directing the electron beam to the evaporation material by means of a magnetic deflecting field. This magnetic field allows the back-scattered electrons, as a possible additional heat source, to be kept away from the substrate.

Both the electrical as well as the mechanical properties of the contacts to be fabricated are influenced through a proper selection of the process parameters.

1. Method for fabricating contacts on carrier substrate-free photovoltaic elements comprising a photoactive front side and a rear side, with which contact is to be made, the rear side being provided with an electrically conducting contact layer, which forms the contacts, wherein the contact layer is formed in its entirety in a vacuum coating process.

2. Method, as claimed in claim 1, wherein the contact layer is fabricated by a thermally driven vacuum high rate coating process in a through-feed procedure in a system through flow without vacuum interruption.

3. Method, as claimed in claim 2, wherein the vacuum high rate coating technique is a high power electron beam evaporation technique.

4. Method, as claimed in claim 2, wherein the through-feed procedure is a dynamic procedure, in which the vacuum high rate coating technique is a continuously operating process, in which the photovoltaic elements are moved through a coating zone at a speed greater than zero.

5. Method, as claimed in claim 1, wherein the contact layer is deposited at a constant layer thickness growth until a desired thickness is reached.

6. Method, as claimed in claim 1, wherein the contact layer composed of successive constant individual sections is deposited.

7. Method, as claimed in claim 1, wherein a dynamic coating rate greater than 0.5 μm*m/min is set.

8. Method, as claimed in claim 1, wherein a temperature for the photovoltaic elements is chosen in such a way that it does not exceed 420° C. in situations where photovoltaic elements made of silicon are used.

9. Method as claimed in claim 1, wherein the contact layer is deposited as a multilayer system, which comprises at least two sublayers and which is produced in a vacuum by successive coating steps.

10. Method, as claimed in claim 1, wherein the contact layer comprises a gradient layer made of a variety of materials.

11. Method, as claimed in claim 1, wherein the contact layer comprises at least two interpenetrating particle flows per particle source in a homogeneously mixed layer.

12. Method, as claimed in claim 1, wherein the contact layer comprises a solderable or bondable layer.

13. Method, as claimed in claim 9, wherein a solderable or bondable layer, which is deposited on the contact layer in vacuum sequence, is a sublayer of a multilayer system.

14. Method, as claimed in claim 1, wherein before or after the deposition of the contact layer, an additional layer is applied by magnetron sputtering.

15. Method, as claimed in claim 14, wherein the additional layer is a layer system.

16. Method, as claimed in claim 14, wherein the additional layer is a gradient layer.

17. Method, as claimed in claim 14, wherein the additional layer is produced by constant layer thickness growth.

18. Method, as claimed in claim 1, wherein between two successive process steps, which are locally separated from each other in a coating system and which exhibit varying process pressure, the pressure is uncoupled from each other selectively by apertures, flow resistors, actively pumped compartments or valves.

19. Method, as claimed in claim 1, wherein the contact layer contains by choice aluminum and/or copper.

20. Method, as claimed in claims 1, wherein a solderable layer or a bondable layer is deposited on the contact layer in vacuum sequence.

21. Method, as claimed in claim 20, wherein the solderable or bondable layer, which is deposited on the contact layer in vacuum sequence, is an additional layer.

22. Method, as claimed in claim 1, wherein the photovoltaic elements are coated so as to be structured and the photovoltaic elements are coated through a mobile or immobile mask.

23. Method, as claimed in claim 1, wherein an electron beam is directed to a crucible with the aid of an additional magnetic field in an evaporator chamber, while at the same time a predominant portion of back-scattered electrons is kept away from the substrate by deflecting field.

24. An arrangement for fabricating contacts on carrier substrate-free photovoltaic elements and which comprises at least one evacuatable vacuum coating chamber, wherein the vacuum coating chamber includes means for fabricating a contact layer.

25. An arrangement, as claimed in claim 24, wherein the means for fabricating a contact layer comprise first sources for the particle flow of a thermally driven vacuum high rate coating process, the first sources being positioned in a vacuum coating chamber transversely to a transport direction of the substrate.

26. An arrangement, as claimed in claim 25, further comprising additional apertures in the particle flow between the first sources and the substrate.

27. An arrangement, as claimed in claim 25, wherein second sources for fabricating a contact layer, for a second particle flow of the thermally driven vacuum high rate coating process are positioned in the substrate transport direction behind the first sources.

28. An arrangement, as claimed in claim 25, wherein an absorbing radiation collector having a high thermal capacity or active cooling is mounted behind the photovoltaic elements, which are to be coated, in the vacuum coating chamber.

29. An arrangement, as claimed in claim 25, wherein radiation shields are mounted in the vacuum coating chamber in an area of an evaporator environment that does not output steam.

30. An arrangement, as claimed in claim 25, wherein a sputter source is mounted in the substrate transport direction so as to be inserted as a subsequent addition in another vacuum coating chamber.

31. An arrangement, as claimed in claim 24, wherein an electron beam evaporation results from a water-cooled copper crucible.

32. An arrangement, as claimed in claim 31, wherein the electron beam evaporation results from a ceramic crucible or from a water-cooled copper crucible that is lined with ceramic.

33. An arrangement, as claimed in claim 32, wherein the ceramic of the ceramic crucible is manufactured on the basis of aluminum oxide or boron nitride.
